(19) United States
(12) Patent Application Publication
(10) Pub. No.: US 2014/0257725 A1
(43) Pub. Date: Sep. 11, 2014

(54) METHOD OF DETERMINING THE RESIDUAL CAPACITY OF A BATTERY

(71) Applicant: IFP Energies nouvelles, Rueil-Malmaison Cedex (FR)

(72) Inventors: Yann CREFF, LES COTES D'AREY (FR); Eric PRADA, LYON (FR); Domenico DI DOMENICO, LYON (FR); Philippe POGNANT-GROS, FRANCHEVILLE (FR)

(73) Assignee: IFP Energies nouvelles, Rueil-Malmaison Cedex (FR)

(21) Appl. No.: 14/199,165

(22) Filed: Mar. 6, 2014

(30) Foreign Application Priority Data
Mar. 6, 2013 (FR) 13/51.991

(51) Int. Cl. G01R 31/36

(52) U.S. Cl. CPC G01R 31/3648
USPC 702/63

(57) ABSTRACT

The invention relates to a method of determining the residual capacity of an electrochemical cell for an electrical energy storage using a no-load voltage model of the cell which is parameterized so that the parameter represents the aging of the cell. Parameterizing the model is achieved from a series of measurements performed on the battery, comprising at least a voltage measurement, a temperature measurement and a current measurement of the cell.

### CROSS REFERENCE TO RELATED APPLICATION

Reference is made to French patent application Ser. No. 13/51.991, filed on Mar. 6, 2013, which application is incorporated herein by reference in its entirety.

### BACKGROUND OF THE INVENTION

1. Field of the Invention

The present invention relates to the study of the aging of batteries for motor vehicles. More particularly, the invention relates to a method of determining the residual capacity of such a battery.

The invention notably relates to electrical traction batteries used in vehicles, notably electrical or hybrid vehicles that require smart management of their electrical energy.

2. Description of the Prior Art

In the present application, “battery” is a generic name for a battery, a pack, a module and a cell. Batteries and packs have one or more electrochemical cells for electrical energy storage (which is the unitary electrochemical component of a battery) and by definition are provided with a battery management system (BMS). Modules are sets of electrochemical cells for energy storage. Hereinafter, the term battery is therefore used to designate both a whole battery or a cell, or a set of cells, with or without a BMS.

During use, several physical characteristics of the cell constituents where are the electrodes and electrolytes vary. This is referred to as aging of the cell. Such aging has various causes, but it notably leads to a change in the no-load voltage of the cell and to a decrease in the capacity thereof. Generally, a battery is considered to reach its end of life when it has lost 30% of its initial capacity.

Knowledge of the residual charge of a battery allows defining a real state of charge defined from a real capacity accounting for the aging of the battery. Furthermore, the residual capacity of the battery also allows to define a state of health (SOH) thereof.

The evolution of the energy of a battery is directly linked with the capacity loss thereof over time. It thus directly depends on the degree of aging of the battery, which is specific to each vehicle use which is the case history of each battery on board the vehicle.

Determining the characteristics of batteries can be done using several types of approaches described in the literature, which are essentially:

approaches based on monitoring, throughout the life of the battery, the electrochemical impedance spectrum SOC and temperature which is parameterized. These approaches are based on all or part of the frequency range of the spectrum,

approaches based on the on-line identification of the value of constituent parameters of an equivalent circuit representative of the operation of the battery. The identification of a simple resistor (equivalent to the internal resistance) and slightly more complex equivalent circuits such as an internal resistance plus one (or more) resistor and capacitor assembly (assemblies) is often found, and

“open loop” approaches allowing calculation of an aging index whose evolution most often depends on the temperature and intensity trajectories, and on the charge or discharge rates. For this type of approaches, empirical formulas (that can use a kinetic analogy with exponential aging laws) or severity maps are found.

To solve these problems, patent applications DE-10-2010-019,128 A1 and FR-2,946,150 A1 describe methods of estimating the capacity of an electrical battery using measurements. However, the methods described in these documents involve several drawbacks.

Notably, they do not enable the aging of the battery to be modelled with precision. The same type of measurement is used for both methods which are two voltages at stabilized points and the integral of the current between these two stabilized points. These methods use the no-load voltage curves. However, the temperature dependence of these curves does not seem to be really exploited. Indeed, for patent application DE-10-2010-019,128 A1, the curve for which the SOC delta given by the integral gives the two measured voltage values is sought from among the available curves giving the no-load voltage as a function of the SOC and the aging. This method does not describe the management of the fact that the two points for which the voltages are measured can be at different temperatures. Patent application FR-2,946,150 A1 uses a different procedure using the notion of slope which is a representation of the no-load voltage by a line between the two measured voltage values. The observation of a certain slope, for a given integral, must correspond, at the given temperature, to a certain residual capacity. This requires a priori knowledge of all of these slopes.

Furthermore, both patent applications use the notion of charge related to the capacity which are the SOC for the German patent application and the depth of discharge for the French patent application for parameterizing the no-load voltages. The French patent application considers that the state of charge is known via the first measured voltage.

For both patent applications, only two measurement points are used, which makes the computations sensitive to voltage and current measurement errors.

Moreover, both patent applications claim to a priori have all the possible no-load voltage curves, which seems to be very difficult since it would require foreseeing the way the cell ages.

### SUMMARY OF THE INVENTION

The invention thus relates to a method of determining the residual capacity of an electrochemical cell by a parameterized model provided by software executed on one or more programmed computers representing the aging of the cell. Parameterizing the model is achieved from a series of measurements performed on the battery. Using the model parameterized by measurements allows precise accounting for the initial state of the battery. The method according to the invention parameterizes the no-load voltage curve by factors representative of aging modes which does not require knowledge of the SOC of the battery. The invention allows exploitation of a large number of measurements for determining the residual capacity, which enables limiting the unwanted effects linked with measurement errors. Finally, the present invention allows use of measurement triplets for which the temperature does not have the same value for the two voltage measurements, which a priori allows frequent updating of the residual capacity.

The invention relates to a method of determining the residual capacity Cᵣₑₛ of at least one electrochemical cell for electrical energy storage. At least one series of measurements are made comprising (1) measurements of a voltage V₀ and of a temperature T₀ at the start of a current drain from the initially relaxed electrochemical cell and (2) of a voltage V₁ and of a temperature T₁ at the end of the current drain from the electrochemical cell and after relaxation thereof, and of a current I during the current drain from the electrochemical cell is carried out. The method comprises carrying out the following stages:

a) determining at least one parameter η representing an effect of the aging of the electrochemical cell by the series of measurements and of a no-load voltage model of the electrochemical cell. The model connects voltage V of the electrochemical cell to charge C of the electrochemical cell, to temperature T, by the parameter η;

b) calculating the residual capacity Cᵣₑₛ by the model and of the parameter η.

According to the invention, the number of series of measurements is greater than or equal to the number of parameters η of the model.

According to an embodiment of the invention, the parameter η is determined by the series of measurements by carrying out the following stages:

i) initializing the parameter η to an initial value η₀;

ii) determining a value for a current drain start capacity C₀ using the model, the temperature and voltage measurements T₀ and V₀ at current drain start, and the parameter η;

iii) determining a current drain end capacity C₁ by adding up the current drain start capacity C₀ and an integral E of current measurement I during the current drain;

iv) estimating a current drain end voltage value V₁^{est} with the model, of the current drain end capacity C₁, of the current drain end temperature T₁ and of the parameter η; and

v) repeating stages ii) to iv) by modifying the parameter η to minimize the difference between measured voltage value V₁ and estimated voltage value V₁^{est}.

Advantageously, said parameter 77 is modified using a descent method.

According to a second embodiment of the invention, a single parameter η is determined by a single series of measurements which seek through a Newtonian algorithm a zero of a function φ(η) of the following type: φ(η)=V₁^{m}−U₀(C₀+Σ^{m},T₁,η) with V₁^{m} and V₀^{m} being the measurements of the current drain end and start voltages of the electrochemical cell, Σ^{m} being the integral of the current measured during the current drain from the electrochemical cell, C₀ being the current drain start capacity determined by the model and of the series of measurements, and U₀ designates the model.

According to a third embodiment of the invention, a single parameter η is determined using the determination of the minimum of a function of the type as follows:

$${min}_{{C}_{0} , Σ , η} {α ( {V}_{0}^{m} - {U}_{0} ( {C}_{0} , {T}_{0} , η ) )}^{2} + {β ( {V}_{1}^{m} - {U}_{0} ( {C}_{0} + Σ , {T}_{1} , η ) )}^{2} + {γ ( {Σ}^{m} - Σ )}^{2}$$

with V₁^{m} and V₀^{m} being the measurements of the current drain end and start voltages of the electrochemical cell, Σ^{m} being the integral of the current measured during the current drain from the electrochemical cell, α, β and γ being weights of the various contributions, C₀ being the current drain start capacity determined by the model and of the series of measurements, and U₀ designating the model.

According to a fourth embodiment of the invention, n parameters η are determined by means of p series of measurements using the determination of the minimum of a function of the form as follows:

$${min}_{\{ {C}_{0}^{i} \} , \{ {Σ}^{i} \} , η} {\sum }_{i = 1}^{p} {{α}_{i} ( {V}_{0}^{m , i} - {U}_{0} ( {C}_{0}^{i} , {T}_{0}^{i} , η ) )}^{2} + {\sum }_{i = 1}^{p} {{β}_{i} ( {V}_{1}^{m , i} - {U}_{0} ( {C}_{0}^{i} + {Σ}^{i} , {T}_{1}^{i} , η ) )}^{2} + {\sum }_{i = 1}^{p} {{γ}_{i} ( {Σ}^{m , i} - {Σ}^{i} )}^{2}$$

with V₁^{m,i} and V₀^{m,i} being the measurements of the current drain end and start voltages of the electrochemical cell for series of measurements i, Σ^{m,i} being the integral of the current measured during the current drain from the electrochemical cell for series of measurements i, αᵢ, βᵢ and γᵢ being the weights of the various contributions for series of measurements i, C₀ⁱ being the current drain start capacity determined by the model and of the series of measurements i, and U₀ designates the model.

Advantageously, the minimum of the function is determined using a non-linear least-squares algorithm of Levenberg-Marquadt type.

According to the invention, the residual capacity Cᵣₑₛ is determined by the following stages:

i) determining an initial capacity Cᵢ of the electrochemical cell for a reference temperature T_{ref}, by the model, of a maximum voltage of the electrochemical cell and of the parameter η,

ii) determining a final capacity C_{f} of the electrochemical cell for the reference temperature T_{ref}, by the model, of a minimum voltage of the electrochemical cell and of the parameter η;

iii) calculating the residual capacity Cᵣₑₛ by the difference between the final capacity C_{f} and the initial capacity Cᵢ.

Furthermore, the residual capacity Cᵣₑₛ can be calculated by a filtered value of the parameter η.

Preferably, the state of health (SOH) of the electrochemical cell is determined by the residual capacity Cᵣₑₛ.

Advantageously, the electrochemical cell is controlled according to the SOH of the electrochemical cell.

Advantageously, the at least one electrochemical cell is used in a hybrid or electrical vehicle which is notably a motor vehicle.

### BRIEF DESCRIPTION OF THE DRAWINGS

Other features and advantages of the method according to the invention will be clear from reading the description hereafter of embodiments given by way of non limitative example, with reference to the accompanying figures wherein:

FIG. 1 illustrates a no-load voltage curve for a battery in a non-aged initial state and for a battery in an aged state;

FIG. 2 illustrates an iso-temperature no-load voltage curve for one example.

### DETAILED DESCRIPTION OF THE INVENTION

The invention relates to a method of determining a residual capacity Cᵣₑₛ of a battery. It should be noted that the generic term “battery” designates here all electrical energy storages and more particularly batteries, packs, modules and electrochemical cells.

What is referred to as the no-load voltage of the battery is a set of temperature-dependent curves connecting the charge withdrawn from full charge to the voltage at the terminals of the cell when it is totally relaxed. That is when no current has been drawn (zero current) for a long enough period for the potentials to return to their zero equilibrium value. According to this definition, full charge corresponds to a maximum no-load voltage V^{max} defined by the cell designer. The battery is considered to be relaxed when the time elapsed since current has been drawn is greater than or equal to a predetermined time, or when, after an end of current draw, the voltage variation over a given period is below a predetermined threshold.

What is referred to as residual capacity of the cell, denoted by Cᵣₑₛ, is the value of the charge withdrawn from full charge for which the no-load voltage is equal to a minimum voltage V^{min} defined by the cell designer. By definition, the cell is considered to be “empty” when this minimum voltage is reached.

The method according to the invention comprises the following stages:

1) determining parameter η of the model

2) determining residual capacity Cᵣₑₛ.

In order to determine parameter η of the model and residual capacity Cᵣₑₛ, battery property measurements are used. According to the invention, at least one series of measurements is performed with each series of measurements comprising at least the following measurements:

temperature T₀ at the start of current drain from the battery,

voltage V₀ at the start of current drain from the battery which is the voltage measured when the battery is relaxed at starting of current drain, at temperature T₀,

temperature T₁ at an end of current drain from the battery,

voltage V₁ at the end of current drain from the battery which is the voltage measured at the end of the relaxation following current drain end at temperature T₁,

current I during current drain from the battery allows calculating of the integral Σ of the current corresponding to the charge variation during current drain from the battery with this integral being homogeneous at a charge (Ah).

1) Determining Parameter η of the Model

During use, several physical characteristics of the constituents (electrodes and electrolytes) of the cell(s) making up the battery vary. This is referred to as aging of the cell. Such aging has various causes, but it notably leads to a change in the no-load voltage of the cell. When aging is taken into account, the no-load voltage of the cell is then considered to depend on temperature as well as on n parameters denoted by η (forming an n-uplet η=(η₁, . . . , ηₙ)) representing the effect of aging. n is selected depending on the available knowledge for modelling the aging. Such modelling is not the object of the present application. Model examples can be found notably in document E. Prada, D. Di Domenico, Y. Creff, J. Bernard, V. Sauvant-Moynot, F. Huet. A Simplified Electrochemical and Thermal Aging Model of LiFePO₄-graphite Li-ion Batteries: Power and Capacity Fade Simulations. Journal of The Electrochemical Society 160 (4) A616-A628, 2013. By way of example, it is possible to represent with a single parameter the phenomenon of aging of the graphite negative electrode of a Li-ion cell by an increase in the surface layer (SEI) resulting from the precipitation on this electrode of the reaction product from the reaction between a solvent contained in the electrolyte and the cyclable lithium.

Prior to determining parameter η, a no-load voltage model of the battery provided by software executed on one or more processors to be studied is constructed. This model represents the evolution of the battery voltage taking battery aging into account. The model therefore connects voltage V of the battery (or cell) to temperature T, to capacity (charge) C (related to current integral E) of the battery (or cell), by use of at least one parameter η representing an effect of the aging of the battery (or cell).

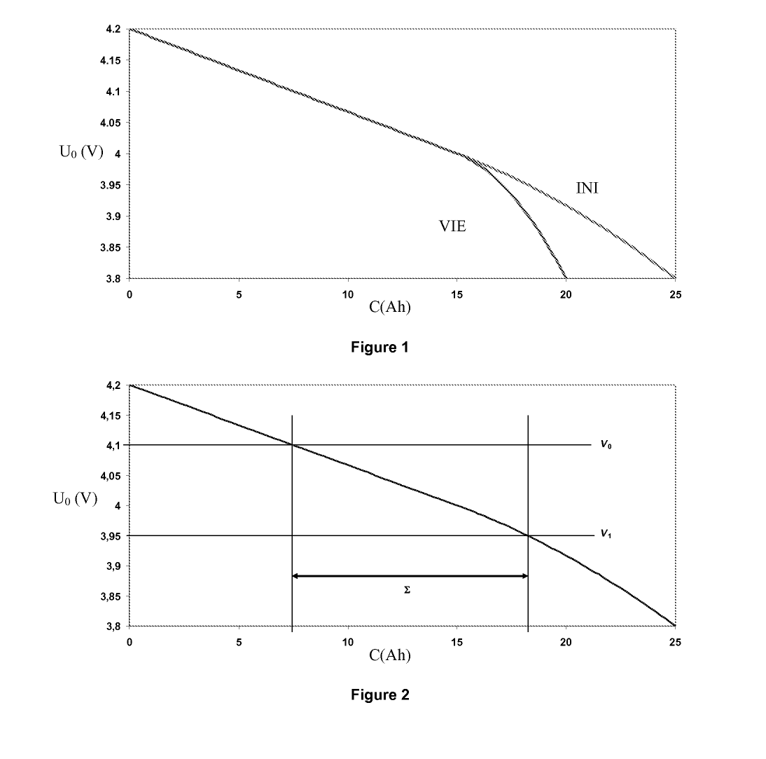

According to the invention, the no-load voltage model is made up of a set of known no-load voltage curves. FIG. 1 shows an example of a no-load voltage curve U₀ (V) as a function of charge C (Ah) for a battery in an initial state, non-aged (INI), and for a battery in an aged state (VIE). It should be noted that the characteristics of the battery in an aged state are degraded from a certain charge. It is this “degradation” that can be modelled by parameter η (or by n-uplet η).

Residual capacity Cᵣₑₛ of the cell depends on the value of parameter η. Without loss of generality, it can be assumed that the cell capacity is given at a reference temperature denoted by T_{ref}. However, all that is presented hereafter is valid in cases where the capacity is a function of temperature.

At a given time of its period of use (its “life”), the no-load voltage of the cell is thus characterized by a value of parameter η (or of n-uplet η).

In the rest of the description below, the term parameter η designates both solutions: a single parameter and an n-uplet.

For a given value of η, assuming that the cell is at the same temperature when measuring V₀ and V₁, these three quantities are such that the representation of FIG. 2 is valid. Such a curve connecting the charge C withdrawn to a no-load voltage U₀ is denoted hereafter by U₀(C, T, η), where T is the temperature. FIG. 2 thus shows an example of an iso-temperature no-load voltage curve U₀ (V) as a function of charge C (Ah). For the example illustrated, maximum voltage V^{max} is 4.2 V, minimum voltage V^{min} is 3.8 V, voltage V₀ at current drain start is 4.1 V, voltage V₁ at current drain end is 3.95 V and residual capacity Cᵣₑₛ of the cell is 25 Ah. The current integral E is also shown in this curve.

By use of the model, it is possible to determine the parameter η. The value of parameter η is thus estimated from the series of previously performed measurements which preferably a p series of measurements with p being greater than or equal to n to estimate parameter η.

According to an embodiment of the invention, a single parameter η can be determined (only one parameter is used to represent aging) by use of a single series of measurements, denoted by Θ=(V₀^{m}, V₁^{m}, Σ^{m}), for which superscript m means measurement. According to this embodiment, the following stages can be carried out:

initializing, assuming that η equals η₀;

calculating, by inversion of model V₀^{m}=U₀(C₀, T₀, η), a value for C₀, the capacity (charge) of the battery at current drain start. If several values of C₀ satisfy the equation, the smallest value is selected if current integral Σ^{m} is positive, the largest is selected if integral Σ^{m} is negative;

determining the quantity for the capacity (charge) C₁ at an end of current drain end by a formula of the type as follows: C₁=C₀+Σ^{m},

estimating a value for current drain end voltage V₁^{est} by use of the model and of the current drain end capacity: V₁^{est}=U₀(C₁, T₁, η);
modifying η and repeating the previous stages until a measurement of the difference between V₁^{est} and V₁^{m} is below a predetermined threshold. The absolute value of the difference or the square of the difference can be selected, for example, as the measurement of the difference for example.

The way η is modified can be based on various existing approaches, such as, for example, descent methods.

According to another embodiment, the number of iterations can be limited to a predetermined maximum amount. If this maximum amount is reached, either the following should be considered, which is the series of measurements are not exploitable and modify the aging state should not be done, or choosing, from among the values of η used in the iterations, the value that gives the smallest measurement of the difference between V₁^{est} and V₁^{m}.

2) Determining Residual Capacity Cᵣₑₛ

Residual capacity Cᵣₑₛ of the battery is determined in this stage from parameter η and from the model.

According to an embodiment of the invention, the following stages can be carried out:

i) determining an initial capacity (charge) Cᵢ of the battery for a reference temperature T_{ref}, by use of the model, of a maximum voltage V^{max} of the battery and of parameter η: V^{max}=U₀(C_{f}, T_{ref}, η),
ii) determining a final capacity (charge) Cᵢ of the battery for a reference temperature T_{ref}, by use of the model, of a minimum voltage V^{min} of the battery and of parameter η: V^{min}=U₀(C_{f}, T_{ref}, η),

iii) calculating the residual capacity Cᵣₑₛ by the difference between the final capacity C_{f} and the initial capacity Cᵢ: Cᵣₑₛ=C_{f}−Cᵢ. The maximum and minimum voltages are provided by the battery manufacturer. These voltage limits Vmax and Vmin depend on the battery technology (chemistry), but also on the operating conditions (temperature and pulsed or continuous drain type).

Stages i) and ii) can be carried out in the order given above, in the opposite order or simultaneously.

These calculations implicitly involve, in stages i) and ii), that the model is locally invertible on C. If, in stage i), the calculation has several solutions for Cᵢ and the smallest value is selected. If, in stage ii), the calculation has several solutions for C_{f} and the largest value is selected.

Residual capacity Cᵣₑₛ can then be used to determine the state of health SOH of the battery. Knowing residual capacity Cᵣₑₛ also allows determination of the value of the real charge of the battery, calculated as a function of the real capacity of the battery and not of the nominal capacity. According to the SOH of the battery, control thereof can be adapted and adjusted to take into account its aged characteristics, and replacing the battery can also be considered if it is regarded as reaching the end of its life (for example after a loss of charge above 30%).

The invention finds applications to batteries for on-board applications: vehicles (motor vehicle, railway, aircraft, watercraft, hovercraft, etc.), telephones, computers, portable tools, autonomous robotic vacuum cleaners, as well as applications referred to as stationary, associated with the intermittent production of electrical power, which also use energy storage systems of battery type.

### Alternative Embodiments

Parameter η can be determined using several variant embodiments.

According to a first alternative embodiment, a single parameter η is determined by a single series of measurements by seeking, with a Newtonian algorithm, the zero value of a function φ(η) of the following type: Φ(η)=V₁^{m}−U₀(C₀+Σ^{m},T₁,η) with V₁^{m} and V₀^{m} being the measurements of the end of current drain end and the start voltages, Σ^{m} being the integral of the current measured during current drain from the battery and C₀ being the current drain start capacity determined by the model and of the series of measurements. Capacity C₀ is the largest solution to V₀^{m}=U₀(C₀,T₀,η) if integral Σ^{m} is positive, otherwise it is the smallest. U₀ designates the model as constructed above.

According to a second alternative embodiment, a single parameter η is determined using the determination of the minimum of a function of the type as follows:

$${min}_{{C}_{0} , Σ , η} {α ( {V}_{0}^{m} - {U}_{0} ( {C}_{0} , {T}_{0} , η ) )}^{2} + {β ( {V}_{1}^{m} - {U}_{0} ( {C}_{0} + Σ , {T}_{1} , η ) )}^{2} + {γ ( {Σ}^{m} - Σ )}^{2}$$

with V₁^{m} and V₀^{m} being the measurements of the current drain end and start voltages, Σ^{m} being the integral of the current measured during current drain from the battery, α, β and γ being weights of the various contributions and C₀ being the current drain start capacity determined by the model and of the series of measurements. Capacity C₀ is the largest solution to V₀^{m}=U₀(C₀,T₀,η) if the integral Σ^{m} is positive or otherwise it is the smallest. U₀ designates the model as constructed above.

For example, if there is great confidence in the value Σ^{m} of the current integral, γ will be selected to be very large compared to β, on the order of α if similar confidence exists (but lesser than in Σ^{m}) in the values of V₀^{m} and V₁^{m}. Measurement of the deviations by squared differences in the above expression is given by way of example.

This minimization problem can be supplemented by simple bounds on the optimization variables. Typically:

C₀ has to be positive and below a maximum value (for example the initial value of the cell capacity, that is when the cell is new. A maximum value above this initial value is preferably chosen)

Σ is of known sign equal to the sign of Σ^{m} with its absolute value ranging between 0 and the value taken as the maximum value for C₀

η is bounded depending on the way the a priori parameterization of the no-load voltage curve is achieved.

Such minimization problems can for example be solved using a non-linear least-squares algorithm of Levenberg-Marquadt type.

According to a third alternative embodiment, n parameters η are determined p series of measurements. It is furthermore assumed that these p series of measurements correspond to measurements at close intervals so that they can be rightfully considered as originating in a single value for η. In other words, the aging rate is assumed to be low so that η can be considered constant during the time interval required for collecting the p series of measurements. With these hypotheses, parameter η is determined using the determination of a minimum of a function of the form as follows:

$${min}_{\{ {C}_{0}^{i} \} , \{ {Σ}^{i} \} , η} {\sum }_{i = 1}^{p} {{α}_{i} ( {V}_{0}^{m , i} - {U}_{0} ( {C}_{0}^{i} , {T}_{0}^{i} , η ) )}^{2} + {\sum }_{i = 1}^{p} {{β}_{i} ( {V}_{1}^{m , i} - {U}_{0} ( {C}_{0}^{i} + {Σ}^{i} , {T}_{1}^{i} , η ) )}^{2} + {\sum }_{i = 1}^{p} {{γ}_{i} ( {Σ}^{m , i} - {Σ}^{i} )}^{2}$$

with V₁^{m,i} and V₀^{m,i} being the measurements of the current drain end and start voltages of the battery for series of measurements i, Σ^{m,i} being the integral of the current measured during the current drain from the battery for series of measurements i, αᵢ, βᵢ and γᵢ being weights (positive real numbers) of the various contributions for series of measurements I and C₀ⁱ the current drain start capacity determined by the model and of series of measurements i.

This minimization problem can be supplemented by simple bounds on the optimization variables. Typically:

C₀ has to be positive and below a maximum value (for example the initial value of the cell capacity, that is when the cell is new. A maximum value above this initial value is preferably chosen)

Σ is of known sign equal to the sign of Σ^{m} with its absolute value ranging between 0 and the value taken as the maximum value for C₀

η is bounded depending on the way the a priori parameterization of the no-load voltage curve is achieved.

Such minimization problems can for example be solved using a non-linear least-squares algorithm of Levenberg-Marquadt type.

The other alternative embodiments relate to the course of the process and they can be combined with one another and with the variants described above.

According to one variant embodiment, at the end of the stage of determining parameter η, a new calculated value η is obtained. One can decide to use this value directly in the stage of determining the residual capacity. Alternatively, one can decide to use, for this stage of determining residual capacity Cᵣₑₛ, a value η_{b} resulting from any filtering of new calculated value η.

There is no a priori guarantee that the problem posed is globally convex. Initialization to the last calculated value (or to the output of any filtering of the last calculated value) can help prevent switching to the basin of attraction of another local minimum. Furthermore, it is possible to either add to the proposed optimization criterion a penalization of the variation of η between two calculations, or to use any global optimization algorithm (multiple shooting with various values for the initialization of η in order to determine a set of local minima). In the latter case of using a global optimization algorithm, the result selected can correspond to the minimum of these minima, but physical considerations may also lead to choose another result. A local minimum for which a monotone aging is obtained (for one or more aging mechanisms) can be preferably selected instead of the minimum of these minima.

The hysteresis effects that can appear (different no-load voltage curves under charge and discharge) can be:

either disregarded, when they are sufficiently low. They then do not affect the calculation results,

or taken into account in the no-load voltage curves parameterization. Then, an information bit giving the sign of the current at the very end of the draw is associated with each Σ^{m,i} (of the third alternative embodiment).

Prior to the stages of determining parameter η and residual capacity Cᵣₑₛ, depending on the number n of parameters used to represent aging, the minimal number p of series of measurements is selected to be considered for updating. This selection is performed according to the battery (or cell) technology and to the alternative embodiment. This selection can be conducted with an iterative procedure. It is based on a set of data corresponding to a succession of states of health of the cell considered. It can also be based on an estimation of the conditioning for the optimization problem to be solved.

The number p of the series of measurements actually used for updating can evolve as updates are being performed, without ever being less than the minimal value defined for p.

Preliminary tests allow ruling out certain series of measurements before the stages of determining parameter η and residual capacity Cᵣₑₛ. For example, it is possible to require that:

the absolute value of integral Σ is strictly greater than a predetermined threshold (it is in any case required to be strictly positive);

the absolute value of the difference between voltages V₀ and V₁ is greater than a predetermined threshold;

the sign of current integral Σ is coherent with the sign of difference V₀−V₁, Σ is positive for a positive difference, otherwise Σ is negative;

the time elapsed between the measurement of V₀ and V₁ is below a predetermined threshold; and

the temperature during the measurement of V₀ and V₁ is contained between predetermined minimum and maximum thresholds.

Furthermore, it is possible to require that the p series of measurements required to be collected over a period of time is below a predetermined maximum threshold.

The criteria used for ruling out a series of measurements can vary from one capacity Cᵣₑₛ update to another.

When p series of valid measurements are available, a calculation is carried out. After that, it is possible, for forming the next set of p series of usable measurements:

to delete the oldest q series of measurements (q can range from 1 to p) and to resume collecting measurements until p series of valid measurements are again available,

to delete q series of measurements (q can range from 1 to p) and to keep only, prior to resuming collecting measurements, the p-q series of measurements considered to be the most representative ones. The representativity of a series of measurements can for example be assessed by the absolute value of integral Σ or by the absolute value of the difference between voltages V₀ and V₁.

The criteria used for forming the next set of p series of usable measurements can vary from one capacity Cᵣₑₛ update to another.

1-13. (canceled)

14. A method of determining residual capacity Cᵣₑₛ of at least one electrochemical cell for electrical energy storage, wherein at least one series of measurements comprising measurements of a voltage V₀ and of a temperature T₀ at starting of a current drain from an initially relaxed electrochemical cell, of a voltage V₁ and of a temperature T₁ at the end of the current drain from the electrochemical cell and after relaxation thereof, and of a current I during the current drain from the electrochemical cell is carried out, the method comprising:
a) determining at least one parameter η representing an effect of aging of the electrochemical cell by the at least one series of measurements and of a no-load voltage model of the electrochemical cell provided by software executed on a programmed computer, the model connecting voltage V of the electrochemical cell to charge C of the electrochemical cell, to temperature T, with the parameter η; and
b) calculating the residual capacity Cᵣₑₛ with the model and the parameter η.

15. A method as claimed in claim 14, wherein a number of the series of measurements is greater than or equal to number of parameters η of the model.

16. A method as claimed in claim 14, wherein the parameter η is determined by a series of measurements by carrying out the following:
i) initializing the parameter η to an initial value η₀;
ii) determining a value for a current drain start capacity C₀ using the model, the temperature and voltage measurements T₀ and V₀ at a start of current drain and the parameter η;
iii) determining a current drain end capacity C₁ by adding up the current drain start capacity C₀ and an integral Σ of current measurement I during the current drain;
iv) estimating a current drain end voltage value V₁^{est} with the model, of the current drain end capacity C₁, of current drain end temperature T₁ and of the parameter η; and
v) repeating ii) to iv) by modifying the parameter η to minimize a difference between measured voltage value V1 and estimated voltage value V₁^{est}.

17. A method as claimed in claim 15, wherein the parameter η is determined by a series of measurements by carrying out the following:
i) initializing the parameter η to an initial value η₀;
ii) determining a value for a current drain start capacity C₀ using the model, the temperature and voltage measurements T₀ and V₀ at a start of current drain and the parameter η;
iii) determining a current drain end capacity C₁ by adding up the current drain start capacity C₀ and an integral Σ of current measurement I during the current drain;
iv) estimating a current drain end voltage value V₁^{est} with the model, of the current drain end capacity C₁, of current drain end temperature T₁ and of the parameter η; and
v) repeating ii) to iv) by modifying the parameter η to minimize a difference between measured voltage value V1 and estimated voltage value V₁^{est}.

18. A method as claimed in claim 16, wherein the parameter η is modified using a descent method.

19. A method as claimed in claim 17, wherein the parameter η is modified using a descent method.

20. A method as claimed in claim 14, wherein a single parameter η is determined by a single series of measurements by seeking through a Newtonian algorithm a zero value of a function φ(η) of the following type:
Φ(η)=V₁^{m}−U₀(C₀+Σ^{m},T₁,η) with V₁^{m} and V₀^{m} being the measurements of the current drain end and start voltages of the electrochemical cell, Σ^{m} being an integral of the current measured during the current drain from the electrochemical cell, C₀ being the current drain start capacity determined by the model and of the series of measurements, and U₀ designates the model.

21. A method as claimed in claim 15, wherein the parameter η is modified using a descent method.

22. A method as claimed in claim 14, wherein a single parameter is determined using a determination of a minimum of a function of the type as follows:
$${min}_{{C}_{0} , Σ , η} {α ( {V}_{0}^{m} - {U}_{0} ( {C}_{0} , {T}_{0} , η ) )}^{2} + {β ( {V}_{1}^{m} - {U}_{0} ( {C}_{0} + Σ , {T}_{1} , η ) )}^{2} + {γ ( {Σ}^{m} - Σ )}^{2}$$
with V₁^{m} and V₀^{m} being the measurements of an end of current drain and start voltages of the electrochemical cell, Σ^{m} being an integral of the current measured during the current drain from the electrochemical cell, α, β and γ being weights of contributions, C₀ being the start current drain capacity determined by the model and of the series of measurements, and U₀ designating the model.

23. A method as claimed in claim 15, wherein a single parameter η is determined using a determination of a minimum of a function of the type as follows:
$${min}_{{C}_{0} , Σ , η} {α ( {V}_{0}^{m} - {U}_{0} ( {C}_{0} , {T}_{0} , η ) )}^{2} + {β ( {V}_{1}^{m} - {U}_{0} ( {C}_{0} + Σ , {T}_{1} , η ) )}^{2} + {γ ( {Σ}^{m} - Σ )}^{2}$$
with V₁^{m} and V₀^{m} being the measurements of an end of current drain and start voltages of the electrochemical cell, Σ^{m} being an integral of the current measured during the current drain from the electrochemical cell, α, β and γ being weights of contributions, C₀ being the start current drain capacity determined by the model and of the series of measurements, and U₀ designating the model.

24. A method as claimed in claim 14, wherein n parameters η are determined by p series of measurements using a determination of a minimum of a function of the form as follows:
$${min}_{\{ {C}_{0}^{i} \} , \{ {Σ}^{i} \} , η} {\sum }_{i = 1}^{p} {{α}_{i} ( {V}_{0}^{m , i} - {U}_{0} ( {C}_{0}^{i} , {T}_{0}^{i} , η ) )}^{2} + {\sum }_{i = 1}^{p} {{β}_{i} ( {V}_{1}^{m , i} - {U}_{0} ( {C}_{0}^{i} + {Σ}^{i} , {T}_{1}^{i} , η ) )}^{2} + {\sum }_{i = 1}^{p} {{γ}_{i} ( {Σ}^{m , i} - {Σ}^{i} )}^{2}$$
with V₁^{m,i} and V₀^{m,i} being the measurements of the end of current drain and start voltages of the electrochemical cell for a series of measurements i, Σ^{m,i} being an integral of current measured during the current drain from the electrochemical cell for a series of measurements i, αᵢ, βᵢ and γᵢ and being weights of contributions for series of measurements i, C₀ⁱ being the current drain start capacity determined by the model and of the series of measurements i, and U₀ designating the model.

25. A method as claimed in claim 16, wherein n parameters η are determined by p series of measurements using a determination of a minimum of a function of the form as follows:
$${min}_{\{ {C}_{0}^{i} \} , \{ {Σ}^{i} \} , η} {\sum }_{i = 1}^{p} {{α}_{i} ( {V}_{0}^{m , i} - {U}_{0} ( {C}_{0}^{i} , {T}_{0}^{i} , η ) )}^{2} + {\sum }_{i = 1}^{p} {{β}_{i} ( {V}_{1}^{m , i} - {U}_{0} ( {C}_{0}^{i} + {Σ}^{i} , {T}_{1}^{i} , η ) )}^{2} + {\sum }_{i = 1}^{p} {{γ}_{i} ( {Σ}^{m , i} - {Σ}^{i} )}^{2}$$
with V₁^{m,i} and V₀^{m,i} being the measurements of the end of current drain and start voltages of the electrochemical cell for a series of measurements i, Σ^{m,i} being an integral of current measured during the current drain from the electrochemical cell for a series of measurements i, αᵢ, βᵢ and γᵢ and being weights of contributions for series of measurements i, C₀ⁱ being the current drain start capacity determined by the model and of the series of measurements i, and U₀ designating the model.

26. A method as claimed in claim 22, wherein the minimum of the function is determined using a non-linear least-squares algorithm of Levenberg-Marquadt type.

27. A method as claimed in claim 23, wherein the minimum of the function is determined using a non-linear least-squares algorithm of Levenberg-Marquadt type.

28. A method as claimed in claim 24, wherein the minimum of the function is determined using a non-linear least-squares algorithm of Levenberg-Marquadt type.

29. A method as claimed in claim 25, wherein the minimum of the function is determined using a non-linear least-squares algorithm of Levenberg-Marquadt type.

30. A method as claimed in claim 14, wherein the residual capacity Cᵣₑₛ is determined by the following:
i) determining an initial capacity Cᵢ of the electrochemical cell for a reference temperature T_{ref}, by the model, of a maximum voltage of the electrochemical cell and of the parameter η;
ii) determining a final capacity C_{f} of the electrochemical cell for the reference temperature by T_{ref}, by the model, of a minimum voltage of the electrochemical cell and of the parameter η; and
iii) calculating the residual capacity Cᵣₑₛ by a difference between the final capacity C_{f} and the initial capacity Cᵢ.

31. A method as claimed in claim 15, wherein the residual capacity Cᵣₑₛ is determined by the following:
i) determining an initial capacity Cᵢ of the electrochemical cell for a reference temperature by T_{ref}, by the model, of a maximum voltage of the electrochemical cell and of the parameter η;
ii) determining a final capacity C_{f} of the electrochemical cell for the reference temperature T_{ref}, by the model, of a minimum voltage of the electrochemical cell and of the parameter η; and
iii) calculating the residual capacity Cᵣₑₛ by a difference between the final capacity C_{f} and the initial capacity Cᵢ.

32. A method as claimed in claim 16, wherein the residual capacity Cᵣₑₛ is determined by the following:
i) determining an initial capacity Cᵢ of the electrochemical cell for a reference temperature T_{ref} by the model, of a maximum voltage of the electrochemical cell and of the parameter η;
ii) determining a final capacity C_{f} of the electrochemical cell for the reference temperature T_{ref}, by the model, of a minimum voltage of the electrochemical cell and of the parameter η; and
iii) calculating the residual capacity Cᵣₑₛ by a difference between the final capacity C_{f} and the initial capacity Cᵢ.

33. A method as claimed in claim 18, wherein the residual capacity Cᵣₑₛ is determined by the following:
i) determining an initial capacity Cᵢ of the electrochemical cell for a reference temperature T_{ref}, by the model, of a maximum voltage of the electrochemical cell and of the parameter η;
ii) determining a final capacity C_{f} of the electrochemical cell for the reference temperature by T_{ref}, by the model, of a minimum voltage of the electrochemical cell and of the parameter η;
iii) calculating the residual capacity Cᵣₑₛ by a difference between the final capacity C_{f} and the initial capacity Cᵢ.

34. A method as claimed in claim 14, wherein the residual capacity Cᵣₑₛ is calculated by a filtered value of the parameter η.

35. A method as claimed claim 14, wherein a SOH of the electrochemical cell is determined by the residual capacity Cᵣₑₛ.

36. A method as claimed in claim 35, wherein the electrochemical cell is controlled according to a SOH of the electrochemical cell.

37. A method as claimed in claim 14, wherein the at least one electrochemical cell is used in a hybrid or electrical vehicle.
